(19) United States
(12) Patent Application Publication
(10) Pub. No.: US 2025/0105117 A1
(43) Pub. Date: Mar. 27, 2025

(54) SEMICONDUCTOR PACKAGES AND METHOD OF FABRICATING THE SAME

(71) Applicant: Samsung Electronics Co., Ltd., Suwon-si (KR)

(72) Inventors: Sangseok HONG, Suwon-si (KR); Jaeseong KIM, Suwon-si (KR); Jeongseok KIM, Suwon-si (KR); Tae Wook KIM, Suwon-si (KR); Yejin LEE, Suwon-si (KR); Jooyoung CHOI, Suwon-si (KR)

(73) Assignee: Samsung Electronics Co., Ltd., Suwon-si (KR)

(21) Appl. No.: 18/619,711

(22) Filed: Mar. 28, 2024

(30) Foreign Application Priority Data
Sep. 26, 2023 (KR) 10-2023-0129039

(51) Int. Cl. H01L 23/498; H01L 23/00; H01L 25/065

(52) U.S. Cl. CPC H01L 23/49822; H01L 23/49816; H01L 24/05; H01L 24/13; H01L 25/0657; H01L 2224/05009; H01L 2224/05025; H01L 2224/13008; H01L 2224/13024; H01L 2225/0652; H01L 2924/01028; H01L 2924/01029; H01L 2924/01079; H01L 2924/1431; H01L 2924/1434; H01L 2924/15311

(57) ABSTRACT

A semiconductor package may include a semiconductor chip, a redistribution layer on the semiconductor chip, a protection pattern covering the redistribution layer, and a connection terminal on the redistribution layer. The redistribution layer may include a redistribution pad on a top surface of the redistribution layer, and the redistribution pad may include a first pad and a second pad on the first pad. The second pad may have a side surface that is inclined and that extends to a top surface of the first pad, and the protection pattern may be spaced apart from the side surface of the second pad and may have a side surface that is inclined and that extends to the top surface of the first pad.

### CROSS-REFERENCE TO RELATED APPLICATIONS

This U.S. non-provisional patent application claims priority under 35 U.S.C. § 119 to Korean Patent Application No. 10-2023-0129039, filed on Sep. 26, 2023, in the Korean Intellectual Property Office, the entire contents of which are hereby incorporated by reference.

### BACKGROUND

The present disclosure relates to semiconductor packages, and in particular, to semiconductor packages with improved electrical and reliability characteristics.

In the semiconductor industry, various package technologies have been developed in order to respond to an increase in demand for large-capacity, thin, and small semiconductor devices and/or electronic products therewith. A semiconductor package is configured to easily use an integrated-circuit chip as a part of an electronic product. In general, the semiconductor package includes a printed circuit board (PCB) and a semiconductor chip, which is mounted on the PCB and is electrically connected to the PCB using bonding wires or solder bumps. The development of the electronics industry has led to an increasing demand for the high functionality, high speed, and miniaturization of semiconductor packages.

### SUMMARY

Some example embodiments of the inventive concepts provide semiconductor packages with improved electrical characteristics and structural stability.

Some example embodiments of the inventive concepts provide methods of fabricating a semiconductor package with improved electrical characteristics and structural stability.

According to an example embodiment of the inventive concepts, a semiconductor package may include a semiconductor chip; a redistribution layer on the semiconductor chip; a protection pattern covering the redistribution layer; and a connection terminal on the redistribution layer. The redistribution layer includes a redistribution pad on a top surface of the redistribution layer, the redistribution pad includes a first pad and a second pad on the first pad. The second pad has a side surface that is inclined and that extends to a top surface of the first pad. The protection pattern is spaced apart from the side surface of the second pad and has a side surface that is inclined and that extends to the top surface of the first pad.

According to an example embodiment of the inventive concepts, a semiconductor package may include a lower redistribution layer; a first semiconductor chip on the lower redistribution layer; an upper redistribution layer on the first semiconductor chip, the upper redistribution layer including a redistribution pad on a top surface of the upper redistribution layer; a second semiconductor chip on the upper redistribution layer; a connection terminal electrically connecting the second semiconductor chip to the upper redistribution layer; and a protection pattern on the upper redistribution layer. The redistribution pad includes a first pad and a second pad on the first pad, the protection pattern has a side surface on the first pad and the side surface of the protection pattern is spaced apart from a side surface of the second pad. The connection terminal includes a first portion on a top surface of the second pad and a second portion between the side surface of the second pad and the side surface of the protection pattern.

According to an example embodiment of the inventive concepts, a semiconductor package may include a lower redistribution layer; a logic chip on the lower redistribution layer;
a connection substrate on the lower redistribution layer enclosing the logic chip in a plan view; a mold layer covering the logic chip and the connection substrate; an upper redistribution layer on the mold layer, the upper redistribution layer including redistribution pads; a protection pattern covering the upper redistribution layer; a memory chip on the upper redistribution layer; and connection terminals on corresponding ones of the redistribution pads, the connection terminals between the upper redistribution layer and the memory chip. Each of the redistribution pads includes a first pad and a second pad on the first pad. The protection pattern covers the first pad and is horizontally spaced apart from the second pad. Each of the connection terminals include a first portion on the second pad and a second portion extending between the second pad and the protection pattern. The second pad and the protection pattern have side surfaces that are inclined and that extend to a top surface of the first pad.

According to an example embodiment of the inventive concepts, a method of fabricating a semiconductor package may include forming a second pad on a first pad; forming a protection pattern to cover the first pad and expose the second pad; placing a connection terminal on the second pad; and bonding the connection terminal to the second pad. The second pad and the protection pattern have side surfaces that are inclined and that extend from a top surface of the first pad . . .

### BRIEF DESCRIPTION OF THE DRAWINGS

FIG. 1 is a sectional view illustrating a semiconductor package according to some example embodiments of the inventive concepts.

FIGS. 2A to 2D are enlarged sectional views illustrating a portion (e.g., P1 of FIG. 1) of a semiconductor package according to some example embodiments of the inventive concepts.

FIGS. 3 and 4 are sectional views illustrating a semiconductor package according to some example embodiments of the inventive concepts.

FIGS. 5, 6, 7, 8A, 9A, and 10A are sectional views illustrating a method of fabricating semiconductor packages according to some example embodiments of the inventive concepts.

FIG. 8B is an enlarged sectional view illustrating a portion P1 of FIG. 8A.

FIGS. 9B and 9C are enlarged sectional views illustrating a portion P1 of FIG. 9A.

FIG. 10B is an enlarged sectional view illustrating a portion P1 of FIG. 10A.

### DETAILED DESCRIPTION

Example embodiments of the inventive concepts will now be described more fully with reference to the accompanying drawings, in which example embodiments are shown. Like reference numerals in the drawings denote like elements, and thus their description will be omitted.

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values or shapes should be construed as including a manufacturing or operational tolerance (e.g., +10%) around the stated numerical values or shapes. When ranges are specified, the range includes all values therebetween such as increments of 0.1%.

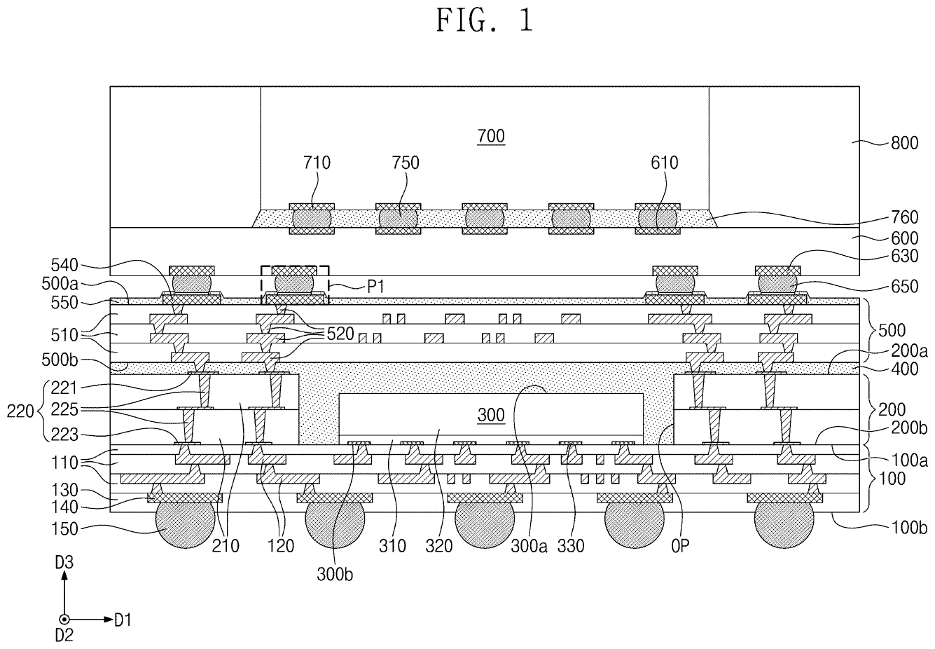

FIG. 1 is a sectional view illustrating a semiconductor package according to some example embodiments of the inventive concepts.

Referring to FIG. 1, the semiconductor package may include a first semiconductor chip 300, a second semiconductor chip 700, and several elements electrically connecting the first semiconductor chip 300 to the second semiconductor chip 700.

A lower redistribution layer 100 may be provided. The lower redistribution layer 100 may include first insulating layers 110, first conductive patterns 120, a passivation layer 130, and outer terminal pads 140. The lower redistribution layer 100 may have a top surface 100a and a bottom surface 100b, which are opposite to each other. The top surface 100a of the lower redistribution layer 100 may be located at a level higher than the bottom surface 100b of the lower redistribution layer 100.

The first insulating layers 110 may be stacked in a vertical direction (e.g., a third direction D3). A thickness of the uppermost one of the first insulating layers 110 may be smaller than thicknesses of the remaining ones of the first insulating layers 110, but the inventive concept is not limited to this example embodiment. That is, the first insulating layers 110 may have substantially the same thickness. A top surface of the uppermost one of the first insulating layers 110 may correspond to the top surface 100a of the lower redistribution layer 100.

The first insulating layers 110 may include a polymer. For example, the first insulating layers 110 may be formed of or include an insulating polymer or a photoimageable dielectric (PID) material. For example, the PID materials may be formed of or include at least one of photoimageable polyimide, polybenzoxazole (PBO), phenol-based polymers, or benzocyclobutene-based polymers. Alternatively, the first insulating layers 110 may include an insulating material. For example, the first insulating layers 110 may be formed of or include at least one of silicon oxide (SiO), silicon nitride (SiN), silicon oxynitride (SiON), or insulating polymers.

The first conductive patterns 120 may be placed in the first insulating layers 110. The first conductive patterns 120 may be configured to electrically connect elements, which are placed on the top and bottom surfaces 100a and 100b of the lower redistribution layer 100, to each other. For example, the first conductive patterns 120 may be elements for horizontal redistribution in the lower redistribution layer 100. The first conductive patterns 120 may include a conductive material. For example, the first conductive patterns 120 may be formed of or include a metallic material (e.g., copper (Cu)).

The first conductive patterns 120 may have a damascene structure. In detail, each of the first conductive patterns 120 may include a wiring line, which is placed on a bottom surface of the first insulating layer 110, and a via, which is extended from the wiring line to protrude in the third direction D3. For example, each of the first conductive patterns 120 may have the shape of an inverted letter ‘T’. The wiring lines of the first conductive patterns 120 may be extended in a horizontal direction (e.g., a first direction D1 or a second direction D2), on the bottom surfaces of the first insulating layers 110. Vias of the first conductive patterns 120 may be provided to penetrate a portion of the first insulating layers 110.

The vias of the first conductive patterns 120 may be used to connect the wiring lines of the first conductive patterns 120, which are adjacent to each other in the third direction D3, to each other. In addition, the vias of the first conductive patterns 120 may be used to electrically connect a connection substrate 200 (to be described below) and the first semiconductor chip 300 to the lower redistribution layer 100. The vias of the first conductive patterns 120 may have a decreasing width, as a distance from the bottom surface 100b of the lower redistribution layer 100 increases in a direction toward the top surface 100a of the lower redistribution layer 100.

The outer terminal pads 140 may be provided on a bottom surface of the lowermost one of the first insulating layers 110. The outer terminal pads 140 may be connected to the vias of the lowermost ones of the first conductive patterns 120. The outer terminal pads 140 may be connected to outer terminals 150, which will be described below.

The passivation layer 130 may be provided on the bottom surface of the lowermost one of the first insulating layers 110. The passivation layer 130 may cover the outer terminal pads 140. Alternatively, the passivation layer 130 may be provided to expose the outer terminal pads 140 to the outside. In this case, the passivation layer 130 may cover the bottom surface of the lowermost one of the first insulating layers 110, but not the bottom surfaces of the outer terminal pads 140. For example, the passivation layer 130 may include an insulating polymer and/or a photoimageable dielectric (PID) material.

The outer terminals 150 may be provided on bottom surfaces of the outer terminal pads 140, respectively. The outer terminals 150 may be provided to penetrate a portion of the passivation layer 130 and may be connected to the outer terminal pads 140. For example, the outer terminals 150 may be formed of or include an alloy including at least one of tin (Sn), silver (Ag), copper (Cu), nickel (Ni), bismuth (Bi), indium (In), antimony (Sb), or cerium (Ce). The semiconductor package may have a ball grid array (BGA) structure, a fine ball-grid array (FBGA) structure, or a land grid array (LGA) structure, depending on the kind or arrangement of the outer terminals 150.

The connection substrate 200 may be provided on the lower redistribution layer 100. The connection substrate 200 may have an opening OP therein. For example, the opening OP may have an open hole that is formed to connect top and bottom surfaces 200a and 200b of the connection substrate 200 to each other. The bottom surface 200b of the connection substrate 200 may be in contact with the top surface 100a of the lower redistribution layer 100. The opening OP may be defined as a space, in which the first semiconductor chip 300 is placed. That is, the first semiconductor chip 300 may be provided in the form of a fan-out panel level package (FO-PLP).

The connection substrate 200 may include base layers 210 and a conductive portion 220, which is placed in the base layers 210. The base layers 210 may be stacked in the third direction D3. For example, a top surface of the uppermost one of the base layers 210 may correspond to the top surface 200a of the connection substrate 200, and a bottom surface of the lowermost one of the base layers 210 may correspond to the bottom surface 200b of the connection substrate 200.

The conductive portion 220 may be disposed between the opening OP and an outer side surface of the connection substrate 200. The conductive portion 220 may include upper pads 221, lower pads 223, and connection vias 225. The upper pads 221 may be disposed on top surfaces of the uppermost one of the base layers 210, but the inventive concepts are not limited to this example embodiment. Thus, the upper pads 221 may be buried in the uppermost one of the base layers 210, and top surfaces of the upper pads 221 may be coplanar with the top surface 200a of the connection substrate 200. The lower pads 223 may be disposed on a bottom surface of the lowermost one of the base layers 210. The lower pads 223 may be buried in the lowermost one of the base layers 210, and bottom surfaces of the lower pads 223 may be coplanar with the bottom surface 200b of the connection substrate 200.

The connection vias 225 may be provided to penetrate the base layers 210 and electrically connect the upper pads 221 to the lower pads 223. Widths on top and bottom surfaces of each connection via 225 may be different from each other. For example, widths of the connection vias 225 in the first and second directions D1 and D2 may increase as a distance from the bottom surface 200b of the connection substrate 200 increases in a direction toward the top surface 200a of the connection substrate 200. That is, the width of each of the connection vias 225 may increase as a height in the third direction D3 increases.

In some example embodiments, the base layers 210 may be formed of or include at least one of insulating polymers, photoimageable dielectric (PID) materials, and/or insulating materials. The upper pads 221, the lower pads 223, and the connection vias 225 may be formed of or include at least one of metallic or conductive materials (e.g., copper (Cu)).

The connection substrate 200 may be mounted on the lower redistribution layer 100. That is, the connection substrate 200 may be in contact with and electrically connected to the lower redistribution layer 100. The vias of the uppermost ones of the first conductive patterns 120 may be provided to penetrate the uppermost one of the first insulating layers 110 and may be connected to the lower pads 223 of the connection substrate 200. Accordingly, the connection substrate 200 may be electrically connected to the outer terminals 150 through the lower redistribution layer 100.

The first semiconductor chip 300 may be provided on the lower redistribution layer 100 and may be placed in the opening OP of the connection substrate 200. The first semiconductor chip 300 may fill a portion of the opening OP. The first semiconductor chip 300 may be in contact with the top surface 100a of the lower redistribution layer 100 exposed through the opening OP. A bottom surface 300b of the first semiconductor chip 300 may be coplanar with the bottom surface 200b of the connection substrate 200 and the top surface 100a of the lower redistribution layer 100. A top surface 300a of the first semiconductor chip 300 may be located at a level lower than the top surface 200a of the connection substrate 200. That is, a height of the first semiconductor chip 300 may be smaller than a height of the connection substrate 200. However, the example embodiments are not limited thereto.

The first semiconductor chip 300 may include a circuit layer 310 and a semiconductor layer 320. The semiconductor layer 320 may be placed on the circuit layer 310, and the circuit layer 310 and the semiconductor layer 320 may be in contact with each other. A bottom surface of the circuit layer 310 may correspond to the bottom surface 300b of the first semiconductor chip 300, and a top surface of the semiconductor layer 320 may correspond to the top surface 300a of the first semiconductor chip 300.

The circuit layer 310 may include first chip pads 330, an integrated circuit, and an insulating pattern. The first chip pads 330 may be placed on the bottom surface of the circuit layer 310. For example, the integrated circuit may be a logic circuit and may consist of at least one transistor or the like. Here, the insulating pattern may cover the integrated circuit but may expose the first chip pads 330 to a region below the bottom surface of the circuit layer 310. That is, the first chip pads 330 may be provided to have bottom surfaces that are coplanar with the bottom surface 300b of the first semiconductor chip 300. In some example embodiments, the first chip pads 330 may be formed of or include various metallic materials (e.g., copper (Cu), aluminum (Al), and/or nickel (Ni)).

In the first semiconductor chip 300, the bottom surface of the circuit layer 310, which includes the integrated circuit, may be an active surface of the first semiconductor chip 300. The top surface of the semiconductor layer 320, which does not include the integrated circuit, may be an inactive surface of the first semiconductor chip 300. That is, the bottom surface 300b of the first semiconductor chip 300 may correspond to the active surface, and the top surface 300a of the first semiconductor chip 300 may correspond to the inactive surface. Since the active surface of the first semiconductor chip 300 is located at a level lower than the inactive surface thereof, the first semiconductor chip 300 may be mounted on the lower redistribution layer 100 in a face-down manner.

In some example embodiments, the first semiconductor chip 300 may be mounted on the top surface 100a of the lower redistribution layer 100 in a direct bonding manner. For example, the bottom surface 300b of the first semiconductor chip 300 may be in contact with the top surface 100a of the lower redistribution layer 100. The first chip pads 330 may be connected to the uppermost ones of the first conductive patterns 120. Accordingly, the first semiconductor chip 300 may be electrically connected to the lower redistribution layer 100. The first semiconductor chip 300 may be electrically connected to the outer terminals 150 through the lower redistribution layer 100. Since a solder ball or a solder bump is omitted from a region between the first semiconductor chip 300 and the lower redistribution layer 100, it may be possible to reduce the size of the semiconductor package.

For example, the first semiconductor chip 300 may be a logic chip. The logic chip may include an application specific integrated circuit (ASIC) chip, an application processor (AP) chip, a central processing unit (CPU), and/or a graphics processing unit (GPU).

A first mold layer 400 may be provided on the connection substrate 200. The first mold layer 400 may cover the connection substrate 200 and the first semiconductor chip 300. The first mold layer 400 may fill a remaining portion of the opening OP. The first mold layer 400 may be extended into a gap region between the connection substrate 200 and the first semiconductor chip 300 and may be in contact with a portion of the lower redistribution layer 100. A portion of the first mold layer 400 may be placed between the connection substrate 200 and the first semiconductor chip 300. Since the first mold layer 400 covers the top surface 200a of the connection substrate 200 and the top surface 300a of the first semiconductor chip 300, a top surface of the first mold layer 400 may be placed at a level higher than the top surface 200a of the connection substrate 200. For example, the first mold layer 400 may be formed of or include an epoxy molding compound (EMC).

Since the first semiconductor chip 300 is veiled by the first mold layer 400 and the connection substrate 200, the first semiconductor chip 300 may be protected from the outside. Accordingly, the first semiconductor chip 300 may not be exposed to an external impact. Thus, the reliability and structural stability of the semiconductor package may be improved.

An upper redistribution layer 500 may be provided on the first mold layer 400. The upper redistribution layer 500 may include second insulating layers 510, second conductive patterns 520, and redistribution pads 540. The upper redistribution layer 500 may have a bottom surface 500b and a top surface 500a, which are opposite to each other. The top surface 500a of the upper redistribution layer 500 may be located at a level higher than the bottom surface 500b of the upper redistribution layer 500.

The second insulating layers 510 may be stacked in a vertical direction (e.g., the third direction D3). In some example embodiments, the second insulating layers 510 may have substantially the same thickness. A top surface of the uppermost one of the second insulating layers 510 may correspond to the top surface 500a of the upper redistribution layer 500. A bottom surface of the lowermost one of the second insulating layers 510 may correspond to the bottom surface 500b of the upper redistribution layer 500. The second insulating layers 510 may include a photoimageable polymer material or an insulating material.

The second conductive patterns 520 may be placed within the second insulating layers 510. The second conductive patterns 520 may be configured to electrically connect elements, which are respectively placed on the top and bottom surfaces 500a and 500b of the upper redistribution layer 500, to each other. For example, the second conductive patterns 520 may be elements for horizontal redistribution in the upper redistribution layer 500. In some example embodiments, the second conductive patterns 520 may be formed of or include at least one of metallic materials (e.g., copper (Cu)).

The second conductive patterns 520 may have a damascene structure, similar to the first conductive patterns 120. In detail, each of the second conductive patterns 520 may include a wiring line, which is provided on the top surfaces of the second insulating layers 510 and the first mold layer 400, and a via, which is extended from the wiring line to protrude in an opposite direction of the third direction D3. That is, each of the second conductive patterns 520 may have the shape of the letter ‘T’. The wiring lines of the second conductive patterns 520 may be extended in a horizontal direction (e.g., the first or second direction D1 or D2), on the top surfaces of the second insulating layers 510 and the first mold layer 400. Vias of the second conductive patterns 520 may be provided to penetrate portions of the second insulating layers 510.

The vias of the second conductive patterns 520 may be configured to connect the wiring lines of the second conductive patterns 520, which are adjacent to each other in the third direction D3, to each other. In addition, the vias of the second conductive patterns 520 may be configured to electrically connect the connection substrate 200 to the upper redistribution layer 500. The vias of the second conductive patterns 520 may have an increasing width, as a distance from the bottom surface 500b of the upper redistribution layer 500 increases in a direction toward the top surface 500a of the upper redistribution layer 500.

The redistribution pads 540 may be located on the top surface of the uppermost one of the second insulating layers 510. That is, the redistribution pads 540 may be placed on the top surface 500a of the upper redistribution layer 500 and may be connected to the uppermost one of the second conductive patterns 520. Top surfaces of the redistribution pads 540 may be located at a level higher than the top surface 500a of the upper redistribution layer 500. That is, the redistribution pads 540 may not be buried in the upper redistribution layer 500, but the inventive concepts are not limited to this example. The redistribution pads 540 may be two-dimensionally arranged in a plan view. That is, the redistribution pads 540 may be spaced apart from each other in a horizontal direction (e.g., the first or second direction D1 or D2).

A protection pattern 550 may be provided on the upper redistribution layer 500. For example, the protection pattern 550 may include at least one of inorganic fillers (e.g., prepreg, Ajinomoto build-up film (ABF), FR-4, and/or bismalcimide triazine (BT)), and/or resins containing glass fibers. The protection pattern 550 may cover the top surface 500a of the upper redistribution layer 500 and portions of the redistribution pads 540. For example, the protection pattern 550 may cover a portion of the redistribution pad 540, which is not in contact with a connection terminal 650 (to be described below). In this case, it may be possible to prevent or reduce in likelihood the redistribution pads 540 from being exposed to the outside and from being oxidized. As a result, the reliability of the semiconductor package may be improved.

The connection terminals 650 may be provided on the upper redistribution layer 500, an interposer substrate 600 may be provided on the connection terminals 650, and the second semiconductor chip 700 may be mounted on the interposer substrate 600.

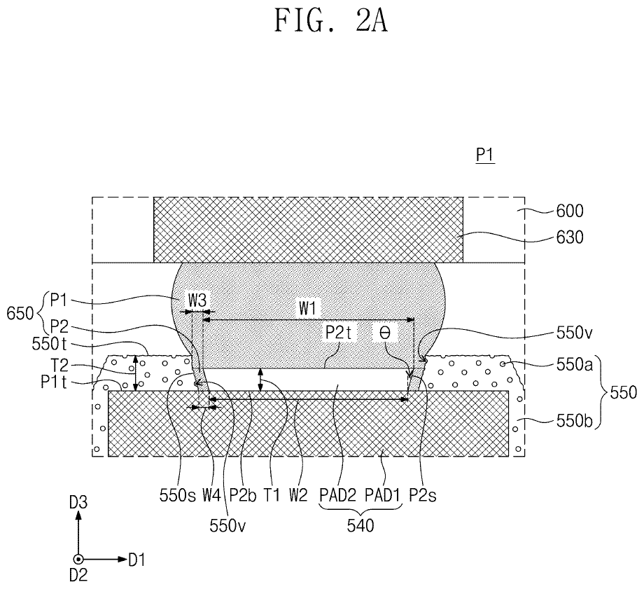

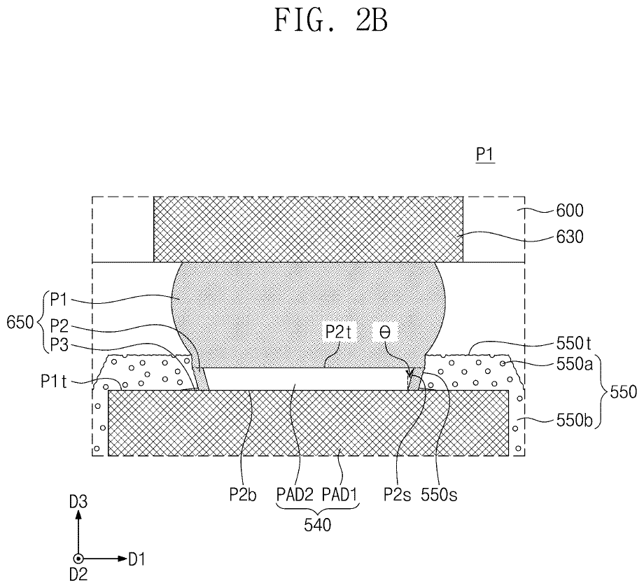

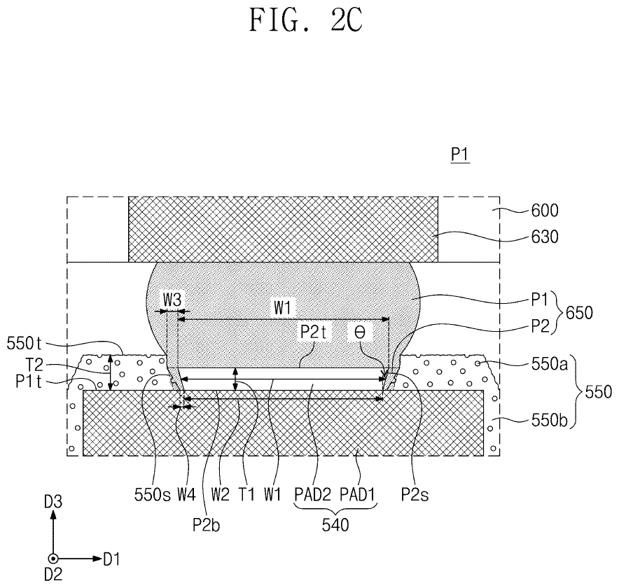

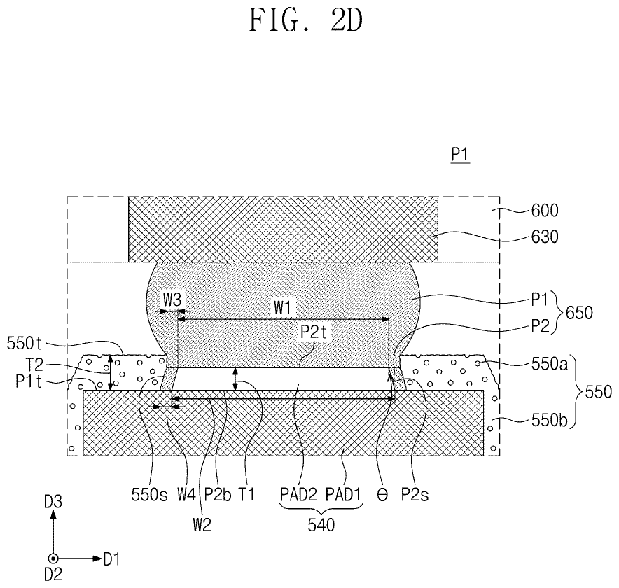

Each of the connection terminals 650 may be placed on a corresponding one of the redistribution pads 540. The connection terminals 650 may be placed between the redistribution pads 540 and lower pads 630 (to be described below) of the interposer substrate 600. The connection terminals 650 may be formed of or include an alloy that contains at least one of tin (Sn), silver (Ag), copper (Cu), nickel (Ni), bismuth (Bi), indium (In), antimony (Sb), or cerium (Ce). The connection terminals 650 and the redistribution pads 540 will be described in more detail with reference to FIGS. 2A to 2D.

The interposer substrate 600 may include upper pads 610, lower pads 630, and interconnection patterns. The upper pads 610 may be placed on a top surface of the interposer substrate 600 and may be exposed by the top surface of the interposer substrate 600. The lower pads 630 may be placed on a bottom surface of the interposer substrate 600 and may be exposed by the bottom surface of the interposer substrate 600. In some example embodiments, top surfaces of the upper pads 610 may be coplanar with the top surface of the interposer substrate 600, and bottom surfaces of the lower pads 630 may be coplanar with the bottom surface of the interposer substrate 600. The upper pads 610 and the lower pads 630 may be spaced apart from each other in the third direction D3. The interconnection patterns may be placed in the interposer substrate 600 and may be configured to electrically connect the upper pads 610 to the lower pads 630. For example, the upper pads 610, the lower pads 630, and the interconnection patterns may be formed of or include at least one of metallic or conductive materials (e.g., copper (Cu)).

The second semiconductor chip 700 may be located on the interposer substrate 600. The second semiconductor chip 700 may include second chip pads 710. The second chip pads 710 may be placed in a lower portion of the second semiconductor chip 700 and may be exposed by a bottom surface of the second semiconductor chip 700. The second chip pads 710 may be horizontally spaced apart from each other. The second semiconductor chip 700 may be a semiconductor chip that is of a different kind from the first semiconductor chip 300. For example, the second semiconductor chip 700 may be a memory chip. The memory chip may include a dynamic random access memory (DRAM) chip.

Chip terminals 750 may be provided between the second semiconductor chip 700 and the interposer substrate 600. The chip terminals 750 may be placed between the second chip pads 710 of the second semiconductor chip 700 and the upper pads 610 of the interposer substrate 600 and may electrically connect the second semiconductor chip 700 to the interposer substrate 600. The chip terminals 750 may be formed of an alloy that contains at least one of tin (Sn), silver (Ag), copper (Cu), nickel (Ni), bismuth (Bi), indium (In), antimony (Sb), or cerium (Ce).

An under-fill layer 760 may be provided between the second semiconductor chip 700 and the interposer substrate 600 to enclose the chip terminals 750. The under-fill layer 760 may cover side surfaces of the chip terminals 750. The under-fill layer 760 may have an inclined side surface, but the inventive concepts are not limited to this example embodiment. Since the chip terminals 750 are not exposed to the outside by the under-fill layer 760, the durability of the chip terminals 750 may be improved.

A second mold layer 800 may be provided on the interposer substrate 600 to enclose the second semiconductor chip 700. The second mold layer 800 may cover a side surface of the second semiconductor chip 700 and a side surface of the under-fill layer 760. A side surface of the second mold layer 800 may be aligned to a side surface of the interposer substrate 600. A top surface of the second mold layer 800 may be coplanar with a top surface of the second semiconductor chip 700, but the inventive concepts are not limited to this example embodiment.

FIGS. 2A to 2D are enlarged sectional views illustrating a portion (e.g., P1 of FIG. 1) of a semiconductor package according to some example embodiment of the inventive concepts.

Referring to FIG. 2A, the redistribution pad 540 may include a first pad PAD1 and a second pad PAD2. For example, the first pad PAD1 may be formed of or include copper (Cu). A top surface P1t of the first pad PAD1 may be parallel to the first and second directions D1 and D2, which are not parallel to each other. The third direction D3, which is not parallel to the first and second directions D1 and D2, may be normal to the top surface P1t of the first pad PAD1. For example, the first direction D1, the second direction D2, and the third direction D3 may be orthogonal to each other.

The second pad PAD2 may be placed on the top surface P1t of the first pad PAD1 and may be in contact with the first pad PAD1. The second pad PAD2 may be formed of or include a metallic material that is different from the first pad PAD1. Accordingly, there may be a visible interface between the first and second pads PAD1 and PAD2. For example, the second pad PAD2 may contain nickel (Ni) and/or gold (Au).

The second pad PAD2 may have a top surface P2t, a bottom surface P2b, and a side surface P2s between the top surface P2t and the bottom surface P2b. The top and bottom surfaces P2t and P2b of the second pad PAD2 may be parallel to the top surface P1t of the first pad PAD1. The second pad PAD2 may have a first thickness T1 in the third direction D3. The second pad PAD2 may have a first width W1, when measured in the first direction D1 at the top surface P2t thereof. The second pad PAD2 may have a second width W2, when measured in the first direction D1 at the bottom surface P2b thereof. The first width W1 may be larger than the second width W2, and thus, the second pad PAD2 may have the side surface P2s that is inclined at an angle to the top surface P1t of the first pad PAD1. For example, the side surface P2s of the second pad PAD2 may be inclined at a constant angle θ to a direction (e.g., the third direction D3) normal to the top surface P1t of the first pad PAD1.

A width of the first pad PAD1 may be larger than the first and second widths W1 and W2 of the second pad PAD2. The second pad PAD2 may be placed to be overlapped with a center of the first pad PAD1 in horizontal directions (e.g., the first and second directions D1 and D2). Accordingly, the second pad PAD2 may be vertically overlapped with the first pad PAD1. When viewed in a plan view, an area of the first pad PAD1 may be larger than an area of the second pad PAD2.

When viewed in a plan view, the first and second pads PAD1 and PAD2 may have a circular shape, but the inventive concepts are not limited to this example. For example, the first and second pads PAD1 and PAD2 may have polygonal shapes (e.g., elliptical, triangular, and rectangular shapes), and in some example embodiments, the first and second pads PAD1 and PAD2 may have different shapes from each other.

The protection pattern 550 may be placed on the first pad PAD1. The protection pattern 550 may cover a side surface and a portion of the top surface P1t of the first pad PAD1 and may expose the second pad PAD2. A side surface 550s of the protection pattern 550 may be spaced apart from the side surface P2s of the second pad PAD2. In other words, the protection pattern 550 may cover the first pad PAD1 and may be horizontally spaced apart from the second pad PAD2. At the top surface P2t of the second pad PAD2, a distance between the side surface P2s of the second pad PAD2 and the side surface 550s of the protection pattern 550 may be a third width W3. At the bottom surface P2b of the second pad PAD2, a distance between the side surface P2s of the second pad PAD2 and the side surface 550s of the protection pattern 550 may be a fourth width W4. The third width W3 and the fourth width W4 may be substantially equal to each other. Since the side surface P2s of the second pad PAD2 is spaced apart from the side surface 550s of the protection pattern 550 by a constant distance, the protection pattern 550 may have the side surface 550s, which is located on and inclined to the top surface P1t of the first pad PAD1. For example, the side surface 550s may extend from or to the top surface P1t of the first pad PAD1. For example, the side surface 550s may form an oblique angle with the top surface P1t of the first pad PAD1.

The protection pattern 550 may have a second thickness T2 in the third direction D3. The second thickness T2 of the protection pattern 550 may be larger than the first thickness T1 of the second pad PAD2. Since a bottom surface of the protection pattern 550 is coplanar with the bottom surface P2b of the second pad PAD2, a top surface 550t of the protection pattern 550 may be located at a level higher than the top surface P2t of the second pad PAD2.

The protection pattern 550 may include a resin 550b and fillers 550a placed in the resin 550b. The fillers 550a may be enclosed by the resin 550b. In other words, the protection pattern 550 may be the resin 550b containing the fillers 550a. For example, the fillers 550a may include an inorganic filler (e.g., silicon oxide or aluminum oxide). A size of each of the fillers 550a may range from about 1 μm to about 5 μm. For example, the resin 550b may be formed of or include a thermosetting resin material (e.g., epoxy resin) or a thermoplastic resin material (e.g., a polyimide).

Voids 550v may be formed at the side surface 550s of the protection pattern 550. The voids 550v may be formed, when the fillers 550a near the side surface 550s of the protection pattern 550 are removed. Owing to the presence of the voids 550v, a roughness of the side surface 550s of the protection pattern 550 may be greater than a roughness of the side surface P2s of the second pad PAD2. In some example embodiments, at least a portion of the void 550v may be filled with the connection terminal 650. A frictional force between the protection pattern 550 and the connection terminal 650 may be increased. This may make it possible to prevent or reduce in likelihood that the connection terminal 650 is detached from the redistribution pad 540.

The connection terminal 650 may include a first portion P1 and a second portion P2, which protrudes from the first portion P1. The first portion P1 may be provided between the second pad PAD2 and the lower pad 630 of the interposer substrate 600. The first portion P1 may be in contact with the top surface P2t of the second pad PAD2. The second portion P2 may be extended into a space between the side surface 550s of the protection pattern 550 and the side surface P2s of the second pad PAD2. That is, the second portion P2 may be in contact with the side surface 550s of the protection pattern 550 and the side surface P2s of the second pad PAD2. In addition, the second portion P2 may be in contact with a portion of the top surface P1t of the first pad PAD1. In some example embodiments, the first and second portions P1 and P2 may be provided to form a single object. In this case, there may be no visible interface between the first and second portions P1 and P2.

Since the side surface 550s of the protection pattern 550 and the side surface P2s of the second pad PAD2 are spaced apart from each other by a constant distance, the upper and lower widths of the second portion P2 may be substantially equal to each other. For example, the upper width of the second portion P2 may be a third width W3, and the lower width of the second portion P2 may be a fourth width W4 that is substantially equal to the third width W3. In other words, the width of the second portion P2 may be constant, regardless of a distance from the top surface P2t of the second pad PAD2. In addition, since the protection pattern 550 and the second pad PAD2 has the side surfaces 550s and P2t that is inclined at an angle to the top surface P1t of the first pad PAD1, the second portion P2 may be extended in a direction inclined to the top surface P1t of the first pad PAD1.

In other words, the connection terminal 650 may be provided to cover the top and side surfaces P2t and P2s of the second pad PAD2, and the second portion P2 of the connection terminal 650, which is located on the side surface P2s of the second pad PAD2, may have a shape extending in a direction that is inclined to the top surface P1t of the first pad PAD1. Accordingly, the second portion P2 of the connection terminal 650 may be engaged with the second pad PAD2 and may not be movable in a vertical direction (e.g., the third direction D3). In other words, the connection terminal 650 may have a clamp shape to be fixed to the second pad PAD2, and this may make it possible to prevent or reduce in likelihood the connection terminal 650 from being detached from the second pad PAD2.

Referring to FIG. 2B, a portion of the protection pattern 550 on the first pad PAD1 may be spaced apart from the top surface P1t of the first pad PAD1 in the third direction D3. That is, a portion of the bottom surface of the protection pattern 550 may be detached from the top surface P1t of the first pad PAD1. Accordingly, a space may be formed between the protection pattern 550 and the first pad PAD1.

The connection terminal 650 may further include a third portion P3. The third portion P3 may be horizontally extended from the second portion P2 and may be placed on the top surface P1t of the first pad PAD1. The third portion P3 may fill a space that is formed between the protection pattern 550 and the first pad PAD1. The third portion P3 may be placed between the bottom surface of the protection pattern 550 and the top surface P1t of the first pad PAD1. That is, the third portion P3 may be stuck between the protection pattern 550 and the first pad PAD1, and thus, connection terminal 650 may be robustly fastened to the redistribution pad 540. In this case, it may be possible to prevent or reduce in likelihood the connection terminal 650 from being detached from the redistribution pad 540.

Referring to FIG. 2C, the side surface 550s of the protection pattern 550 may be horizontally spaced apart from the side surface P2s of the second pad PAD2. The side surface 550s of the protection pattern 550 may have a slope different from the side surface P2s of the second pad PAD2. Accordingly, a horizontal distance between the side surface 550s of the protection pattern 550 and the side surface P2s of the second pad PAD2 may be changed depending on a height in the third direction D3. For example, a distance between the side surface P2s of the second pad PAD2 and the side surface 550s of the protection pattern 550 may be a third width W3, at the top surface P2t of the second pad PAD2. A distance between the side surface P2s of the second pad PAD2 and the side surface 550s of the protection pattern 550 may be a fourth width W4, at the bottom surface P2b of the second pad PAD2. Here, the third width W3 may be larger than the fourth width W4. In other words, a horizontal distance between the side surface P2s of the second pad PAD2 and the side surface 550s of the protection pattern 550 may decrease as a distance to the top surface P1t of the first pad PAD1 decreases.

Since the horizontal distance between the side surface 550s of the protection pattern 550 and the side surface P2s of the second pad PAD2 depends on the height in the third direction D3, upper and lower widths of the second portion P2 may be different from each other. For example, the upper width of the second portion P2 may be the third width W3, and the lower width of the second portion P2 may be the fourth width W4. The upper width of the second portion P2 may be larger than the lower width. That is, the second portion P2 may have a decreasing width as a distance to the top surface P1t of the first pad PAD1 decreases.

Referring to FIG. 2D, the second pad PAD2 may have a first width W1 in the first direction D1 at the top surface P2t thereof. The second pad PAD2 may have a second width W2 in the first direction D1 at the bottom surface P2b thereof. In some example embodiments, the first width W1 may be smaller than the second width W2. In other words, the second pad PAD2 may have a decreasing width as a distance from the top surface P1t of the first pad PAD1 increases. Accordingly, the side surface P2s of the second pad PAD2 may be inclined at an angle to the top surface P1t of the first pad PAD1, but the angle may be different from that of the side surface P2s in FIGS. 2A to 2C. For example, the side surface P2s of the second pad PAD2 may be inclined at a constant angle θ to a direction (e.g., the third direction D3) normal to the top surface P1t of the first pad PAD1.

Unlike the example embodiments of FIGS. 2A to 2C, the second portion P2 of the connection terminal 650 may be fastened to the protection pattern 550. For example, the connection terminal 650 may include two wing-shaped portions, with the distance between them increasing as the distance to the top surface P1t of the first pad PAD1 decreases, and due to this structure, the connection terminal 650 may be robustly fastened to the protection pattern 550. Thus, it may be possible to prevent or reduce in likelihood the connection terminal 650 from being detached from the protection pattern 550.

Referring back to FIGS. 2A to 2D, the first portion P1 of the connection terminal 650 may be in contact with the top surface P2t of the second pad PAD2. The second portion P2 of the connection terminal 650 may be in contact with the side surface P2s of the second pad PAD2. Accordingly, a contact area between the connection terminal 650 and the second pad PAD2 may be increased. This may make it possible to improve the electrical characteristics of the semiconductor package.

In addition, the second portion P2 of the connection terminal 650 may be provided to have a shape, which is inclined to the top surface P1t of the first pad PAD1, between the protection pattern 550 and the second pad PAD2. That is, the second portion P2 of the connection terminal 650 may have an anchoring structure, between the protection pattern 550 and the second pad PAD2. Accordingly, the connection terminal 650 may be fastened to the second pad PAD2 and the protection pattern 550. In this case, since the connection terminal 650 is not movable in a vertical direction, the detaching issue of the connection terminal 650 may be prevented or reduced in likelihood. Furthermore, the second portion P2 of the connection terminal 650 may be used to disperse pressure exerted from an upper element (e.g., the interposer substrate 600 and the second semiconductor chip 700) of a semiconductor package. Thus, the reliability of the semiconductor package may be improved.

However, if an angle between the side surface P2s of the second pad PAD2 and the normal direction (e.g., the third direction D3) to the top surface P1t of the first pad PAD1 is too small, the connection terminal 650 may not be fastened to the second pad PAD2 and the protection pattern 550. If the angle of the side surface P2s of the second pad PAD2 to the third direction D3 is too large, there may be a difficulty in stably forming the second portion P2. In this case, an air gap may be formed between the protection pattern 550 and the second pad PAD2. This may mean that it is necessary to control the angle within a specific range. For example, the angle of the side surface P2s of the second pad PAD2 to the third direction D3 may range from about 3° to about 20°.

In addition, if the second portion P2 of the connection terminal 650 is formed to have a small vertical length and a small horizontal width, the connection terminal 650 may not be fastened to the second pad PAD2 and the protection pattern 550. By contrast, if the second portion P2 of the connection terminal 650 is formed to have a large vertical length and a large horizontal width, it may be difficult to reduce the size of the semiconductor package. This may mean that it is necessary to control the size of the second portion P2 of the connection terminal 650 within a specific range. In some example embodiments, the vertical length of the second portion P2 of the connection terminal 650 may range from about 3 μm to about 5 μm, and the horizontal width may range from about 1 μm to about 4 μm.

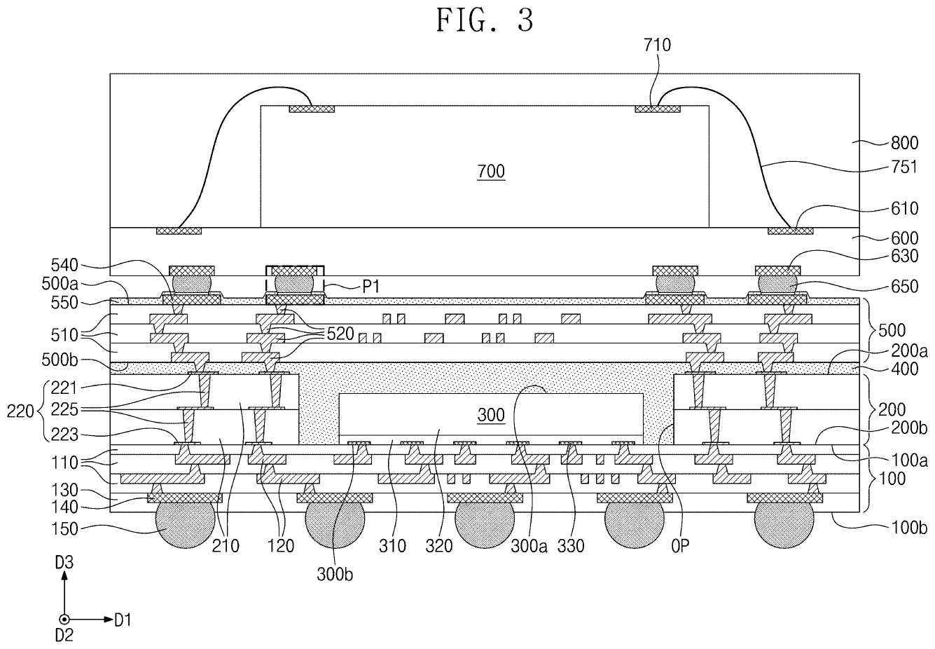

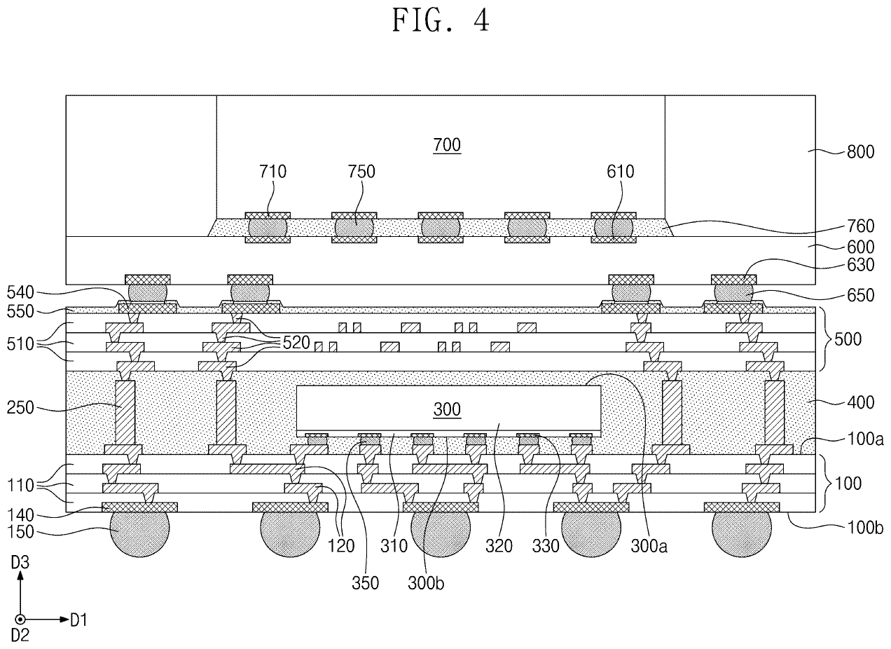

FIGS. 3 and 4 are sectional views illustrating a semiconductor package according to some example embodiments of the inventive concepts.

In the following description, an element previously described with reference to FIG. 1 may be identified by the same reference number without repeating an overlapping description thereof, for concise description.

Referring to FIG. 3, the semiconductor package may include the lower redistribution layer 100, the connection substrate 200, the first semiconductor chip 300, the first mold layer 400, the upper redistribution layer 500, the interposer substrate 600, the second semiconductor chip 700, and the second mold layer 800. The lower redistribution layer 100, the connection substrate 200, the first semiconductor chip 300, the first mold layer 400, and the upper redistribution layer 500 may be configured to have substantially the same features as those in the example embodiments of FIG. 1.

The second semiconductor chip 700 may be located on the interposer substrate 600. The second semiconductor chip 700 may be in direct contact with the interposer substrate 600. The bottom surface of the second semiconductor chip 700 may be located at the same level as the top surface of the interposer substrate 600. That is, the chip terminals 750 and the under-fill layer 760 of FIG. 1 may be omitted.

The second semiconductor chip 700 may include the second chip pads 710. The second chip pads 710 may be placed on the top surface of the second semiconductor chip 700 and may be exposed by the top surface of the second semiconductor chip 700. That is, top surfaces of the second chip pads 710 may be coplanar with the top surface of the second semiconductor chip 700.

Bonding wires 751 may be provided on the second semiconductor chip 700. The bonding wires 751 may be connected to the second chip pads 710 of the second semiconductor chip 700 and the upper pads 610 of the interposer substrate 600. The bonding wires 751 may electrically connect the second semiconductor chip 700 to the interposer substrate 600.

The second mold layer 800 may be provided on the interposer substrate 600 to cover the second semiconductor chip 700 and the bonding wires 751. Since the second mold layer 800 covers the bonding wires 751 on the second semiconductor chip 700, the second mold layer 800 may have a top surface that is located at a level higher than the top surface of the second semiconductor chip 700.

Referring to FIG. 4, the semiconductor package may include the lower redistribution layer 100, the connection substrate 200, the first semiconductor chip 300, the first mold layer 400, the upper redistribution layer 500, the interposer substrate 600, the second semiconductor chip 700, and the second mold layer 800. The interposer substrate 600, the second semiconductor chip 700, and the second mold layer 800 may be configured to have substantially the same features as those in the example embodiments of FIG. 1.

The first insulating layers 110 of the lower redistribution layer 100 may be stacked in a vertical direction (e.g., the third direction D3), and the first conductive patterns 120 may be placed in the first insulating layers 110. In detail, each of the first conductive patterns 120 may include a wiring line, which is placed on the top surface of the first insulating layers 110, and a via, which is extended from the wiring line to protrude in an opposite direction of the third direction D3. For example, each of the first conductive patterns 120 may have the shape of the letter ‘T’. The wiring lines of the first conductive patterns 120 may be extended in a horizontal direction (e.g., the first or second direction D1 or D2), on the top surfaces of the first insulating layers 110. The vias of the first conductive patterns 120 may be provided to penetrate a portion of the first insulating layers 110. The vias of the first conductive patterns 120 may have an increasing width, as a distance from the bottom surface 100b of the lower redistribution layer 100 increases in a direction toward the top surface 100a of the lower redistribution layer 100.

The outer terminal pads 140 may be placed on the bottom surface of the lowermost one of the first insulating layers 110 and may be exposed by the lowermost one of the first insulating layers 110. For example, the bottom surfaces of the outer terminal pads 140 may be coplanar with the bottom surface of the lowermost one of the first insulating layers 110. The outer terminal pads 140 may be connected to the lowermost ones of the first conductive patterns 120.

The first semiconductor chip 300 may be placed on the lower redistribution layer 100 and may be placed in a center region of the lower redistribution layer 100, when viewed in a plan view. The first semiconductor chip 300 may be configured to have substantially the same features as that in the example embodiments of FIG. 1. Bumps 350 may be provided between the first semiconductor chip 300 and the lower redistribution layer 100. Accordingly, the bottom surface 300b of the first semiconductor chip 300 may be spaced apart from the top surface 100a of the lower redistribution layer 100 in the third direction D3. Each of the bumps 350 may be placed between the corresponding uppermost one of the first conductive patterns 120 and the first chip pad 330. That is, the first semiconductor chip 300 and the lower redistribution layer 100 may be electrically connected to each other through the bumps 350. For example, the bumps 350 may be formed of or include an alloy containing at least one of tin (Sn), silver (Ag), copper (Cu), nickel (Ni), bismuth (Bi), indium (In), antimony (Sb), or cerium (Ce).

Penetration vias 250 may be provided on the top surface 100a of the lower redistribution layer 100. The penetration vias 250 may be horizontally spaced apart from the first semiconductor chip 300. For example, the penetration vias 250 may be placed on an edge region of the lower redistribution layer 100, and here, the edge region of the lower redistribution layer 100 may enclose the center region of the lower redistribution layer 100, in which the first semiconductor chip 300 is provided. That is, the penetration vias 250 may be provided to enclose the first semiconductor chip 300, when viewed in a plan view.

The penetration vias 250 may be placed on the uppermost ones of the first conductive patterns 120. The penetration vias 250 may be horizontally spaced apart from each other. Each of the penetration vias 250 may have a shape extending in the third direction D3, e.g., each of the penetration vias 250 may have a greatest dimension in the third direction D3. The penetration vias 250 may be configured to electrically connect the lower redistribution layer 100 to the upper redistribution layer 500. For example, the penetration vias 250 may be formed of or include at least one of metallic or conductive materials (e.g., copper (Cu)).

The first mold layer 400 may be provided on the lower redistribution layer 100. The first mold layer 400 may cover the top surface 300a, the bottom surface 300b, and the side surface of the first semiconductor chip 300 and the side surfaces of the penetration vias 250. The first mold layer 400 may be placed between the penetration vias 250 and between the penetration vias 250 and the first semiconductor chip 300. In other words, the first mold layer 400 may enclose the first semiconductor chip 300 and the penetration vias 250. A side surface of the first mold layer 400 may be aligned to a side surface of the lower redistribution layer 100.

The first mold layer 400 may have a top surface that is parallel to the first and second directions D1 and D2. The top surface of the first mold layer 400 may be located at a level higher than the top surface 300a of the first semiconductor chip 300. The top surface of the first mold layer 400 may be located at a level higher than top surfaces of the penetration vias 250, but the inventive concept is not limited to this example. That is, the top surface of the first mold layer 400 may be coplanar with the top surfaces of the penetration vias 250. In an example embodiment, the first mold layer 400 may include an insulating polymer (e.g., an epoxy molding compound (EMC)).

The upper redistribution layer 500 may be provided on the first mold layer 400. The upper redistribution layer 500 may include the second insulating layers 510, the second conductive patterns 520, and the redistribution pads 540. The upper redistribution layer 500 may be configured to have substantially the same features as that in the example embodiments of FIG. 1. However, the lowermost ones of the second conductive patterns 520 may be placed on and connected to the penetration vias 250, respectively. In this case, the upper redistribution layer 500 and the lower redistribution layer 100 may be electrically connected to each other through the penetration vias 250.

The redistribution pads 540, the protection pattern 550, and the connection terminals 650 may be provided on the top surface of the uppermost one of the second insulating layers 510. The redistribution pads 540, the protection pattern 550, and the connection terminals 650 may be configured to have substantially the same features as those in the example embodiments described with reference to FIGS. 1 and 2A to 2D.

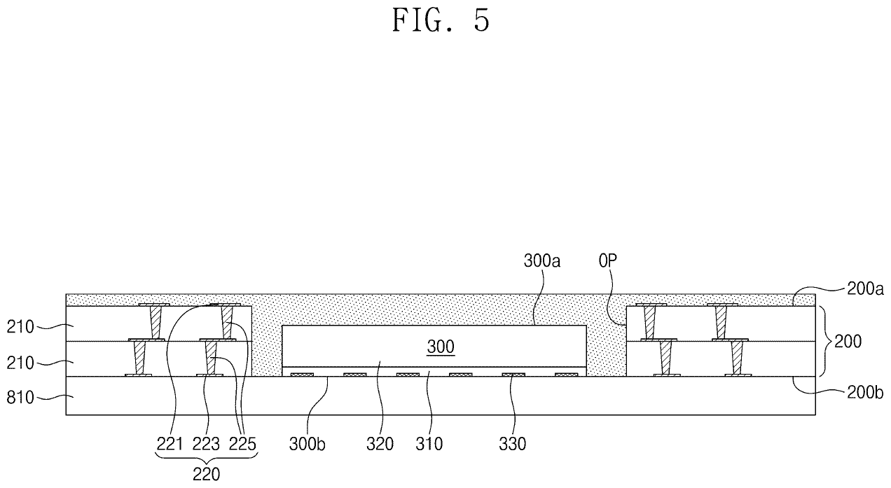

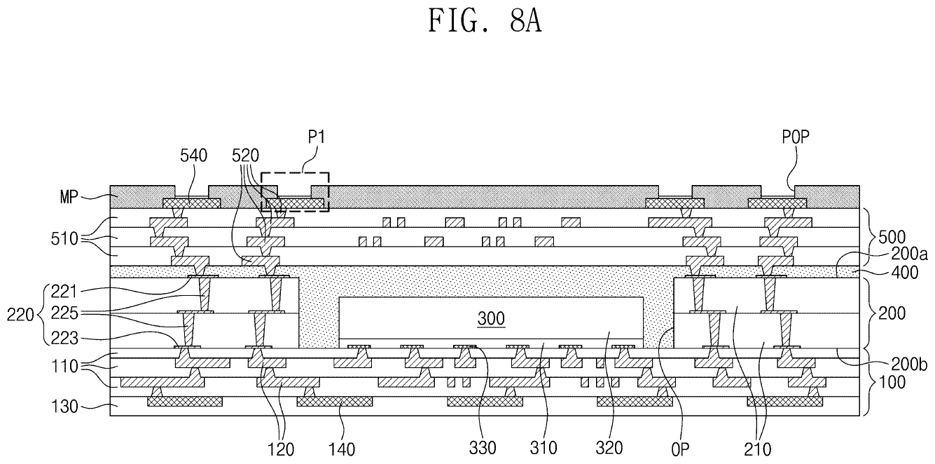

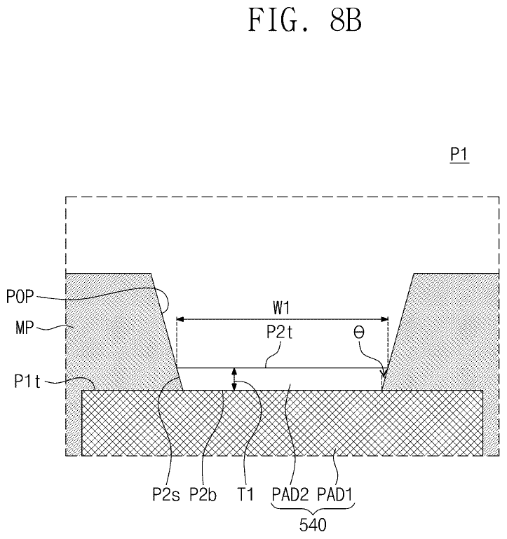

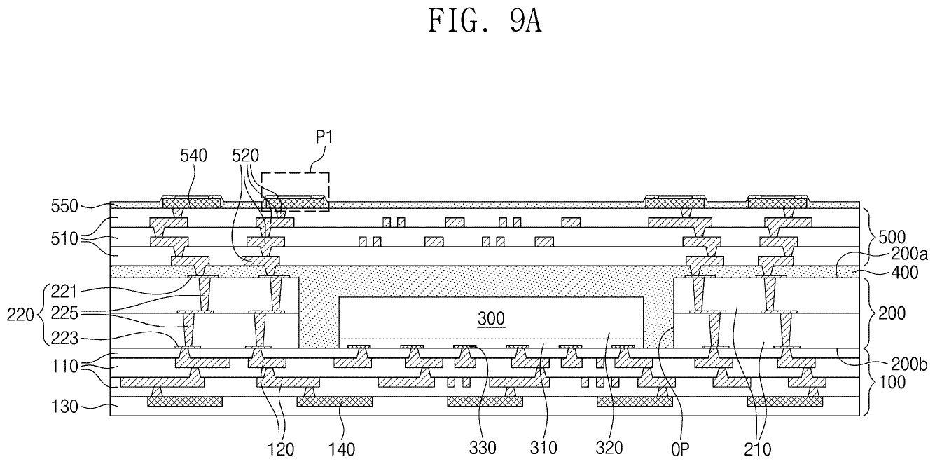

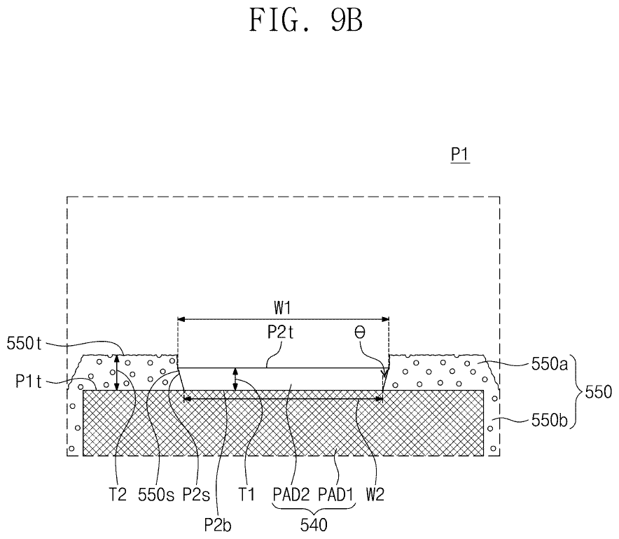

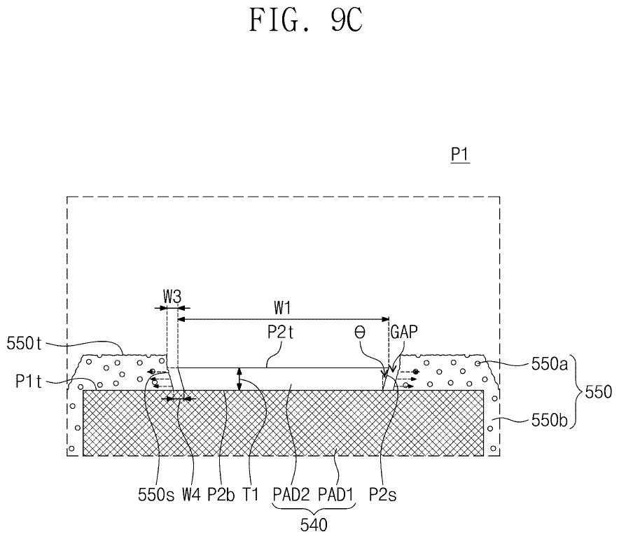

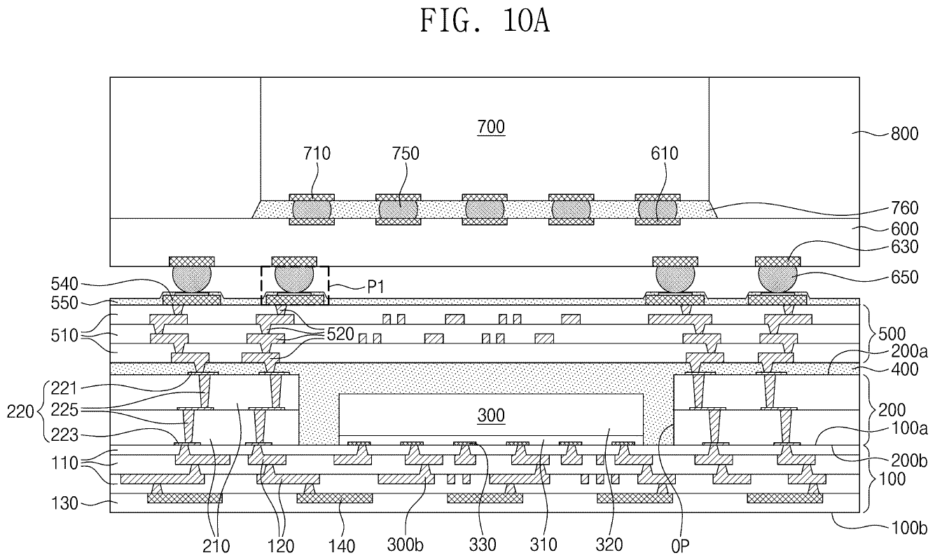

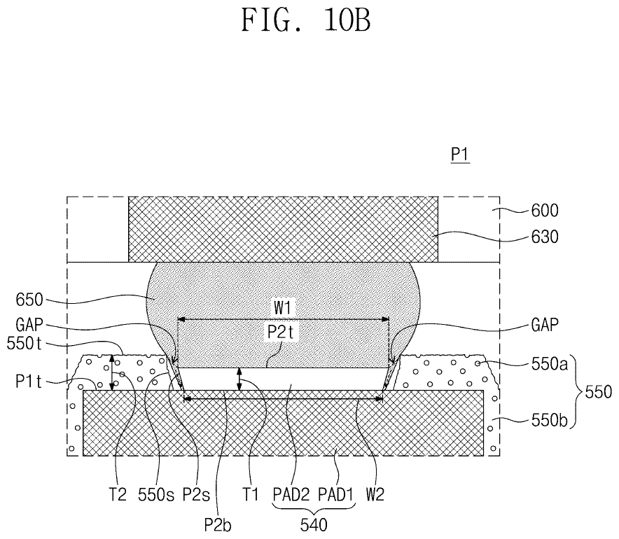

FIGS. 5, 6, 7, 8A, 9A, and 10A are sectional views illustrating a method of fabricating a semiconductor package according to example embodiments of the inventive concepts. FIG. 8B is an enlarged sectional view illustrating a portion P1 of FIG. 8A. FIGS. 9B and 9C are enlarged sectional views illustrating a portion P1 of FIG. 9A. FIG. 10B is an enlarged sectional view illustrating a portion P1 of FIG. 10A.

Referring to FIG. 5, the connection substrate 200 may be formed. The connection substrate 200 may include the base layers 210 and the conductive portion 220. The conductive portion 220 may include the upper pads 221, the lower pads 223, and the connection vias 225. A lower one of the base layers 210 and the conductive portion 220 therein may be formed, and then, an upper one of the base layers 210 and the conductive portion 220 therein may be formed.

Thereafter, the opening OP may be formed in the connection substrate 200. The opening OP may be formed by removing a portion of the connection substrate 200. The opening OP may be formed to penetrate the connection substrate 200 from the top surface 200a to the bottom surface 200b. In some example embodiments, the opening OP may be formed through an etching process, a drilling process, a laser ablation process, or a laser cutting process.

After the formation of the opening OP, a first carrier substrate 810 may be formed on the bottom surface 200b of the connection substrate 200. The first carrier substrate 810 may cover the bottom surface 200b of the connection substrate 200 and may close the opening OP. In some example embodiments, the first carrier substrate 810 may be an insulating substrate, which includes glass or polymer, or a conductive substrate, which includes a metallic material.

The first semiconductor chip 300 may be placed on the first carrier substrate 810 and in the opening OP of the connection substrate 200. The first semiconductor chip 300 may fill a portion of the opening OP. The first semiconductor chip 300 may include the circuit layer 310, the semiconductor layer 320 on the circuit layer 310, and the first chip pads 330 in the circuit layer 310. The first semiconductor chip 300 may be attached to the first carrier substrate 810. That is, the bottom surface 300b of the first semiconductor chip 300 may be coplanar with the bottom surface 200b of the connection substrate 200, and the circuit layer 310 of the first semiconductor chip 300 may be in contact with the first carrier substrate 810.

Next, the first mold layer 400 may be formed to cover the connection substrate 200 and the first semiconductor chip 300. The top surface of the first mold layer 400 may be located at a level higher than the top surface 300a of the first semiconductor chip 300 and the top surface 200a of the connection substrate 200. The first mold layer 400 may fill a remaining portion of the opening OP. The first mold layer 400 may be extended into a gap region between the connection substrate 200 and the first semiconductor chip 300. For example, a portion of the first mold layer 400 may be formed between the connection substrate 200 and the first semiconductor chip 300. The formation of the first mold layer 400 may include injecting a molding member into the gap region between the connection substrate 200 and the first semiconductor chip 300 and curing the molding member.

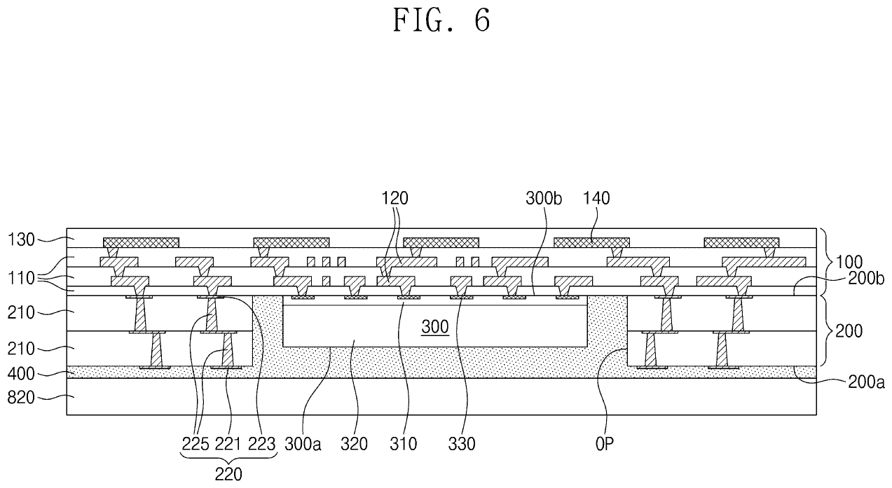

Referring to FIG. 6, a second carrier substrate 820 may be formed on the first mold layer 400. The second carrier substrate 820 may cover the top surface of the first mold layer 400. In some example embodiments, an adhesive member may be provided between the second carrier substrate 820 and the first mold layer 400.

Thereafter, the second carrier substrate 820 may be inverted. In other words, the second carrier substrate 820 may be placed below the first carrier substrate 810, and the connection substrate 200 may be placed between the second carrier substrate 820 and the first carrier substrate 810. Accordingly, the bottom surface 200b of the connection substrate 200 may be placed at a level higher than the top surface 200a.

The first carrier substrate 810 may be removed after the inversion of the second carrier substrate 820. Accordingly, the bottom surface 200b of the connection substrate 200, the bottom surface 300b of the first semiconductor chip 300, and a portion of the first mold layer 400 placed between the first semiconductor chip 300 and the connection substrate 200 may be exposed to the outside.

After the removal of the first carrier substrate 810, the lower redistribution layer 100 may be formed on the bottom surface 200b of the connection substrate 200. The formation of the lower redistribution layer 100 may include forming a first insulating layer 110 on the connection substrate 200 and the first semiconductor chip 300, patterning the first insulating layer 110 using a photolithography and etching process, forming a conductive layer on the patterned first insulating layer 110, and patterning the conductive layer to form the first conductive pattern 120. The first conductive patterns 120 may be respectively connected to the first chip pads 330 of the first semiconductor chip 300 and the lower pads 223 of the connection substrate 200.

The process of forming the lower redistribution layer 100 may be repeatedly performed to form the first insulating layers 110, which are vertically stacked, and the first conductive patterns 120, which are respectively formed in the first insulating layers 110.

Next, the outer terminal pads 140 and the passivation layer 130 may be formed on the first insulating layer 110. The passivation layer 130 may cover the outer terminal pads 140 and the first insulating layer 110. Accordingly, the outer terminal pads 140 and the first insulating layer 110 may be protected from a subsequent process.

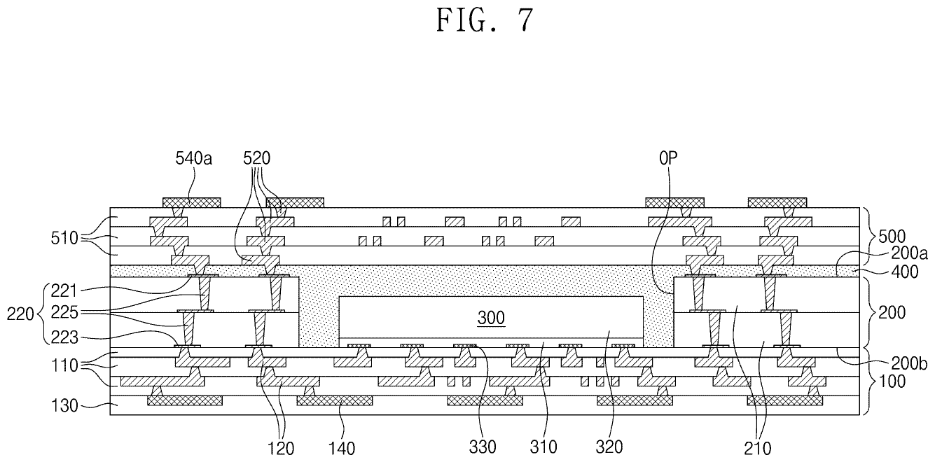

Referring to FIG. 7, the second carrier substrate 820 may be inverted again. Thus, the second carrier substrate 820 may be placed at an upper level. The top surface 200a of the connection substrate 200 may be placed at a level higher than the bottom surface 200b. Thereafter, the second carrier substrate 820 may be removed. As a result of the removal of the second carrier substrate 820, the first mold layer 400 may be exposed to the outside.

Next, the upper redistribution layer 500 may be formed on the first mold layer 400. The formation of the upper redistribution layer 500 may include forming the second insulating layer 510 on the first mold layer 400, patterning the second insulating layer 510 using a photolithography and etching process, forming a conductive layer on the patterned second insulating layer 510, and patterning the conductive layer to form the second conductive pattern 520. The process of forming the upper redistribution layer 500 may be repeatedly performed to form the second insulating layers 510, which are vertically stacked, and the second conductive patterns 520, which are respectively formed in the second insulating layers 510.

The formation of the upper redistribution layer 500 may be substantially the same process as the formation of the lower redistribution layer 100. Each of the second conductive patterns 520 may be connected to a corresponding one of the upper pads 221 of the connection substrate 200.

Preliminary redistribution pads 540a may be formed on the uppermost one of the second insulating layers 510. The preliminary redistribution pads 540a may be located at the same level and may be horizontally spaced apart from each other. Each of the preliminary redistribution pads 540a may be connected to a corresponding one of the uppermost ones of the second conductive patterns 520. For example, the preliminary redistribution pads 540a may be formed of or include a metallic material (e.g., copper (Cu)).

Referring to FIGS. 8A and 8B, the redistribution pads 540, each of which includes the first and second pads PAD1 and PAD2, may be formed from the preliminary redistribution pads 540a. For example, the preliminary redistribution pads 540a may correspond to the first pad PAD1 of each of the redistribution pads 540. The redistribution pad 540 may be a structure which includes the preliminary redistribution pad 540a and the second pad PAD2 formed thereon.

The formation of the redistribution pads 540 may include forming a mask pattern MP on the first pad PAD1 to expose a portion of the top surface P1t of the first pad PAD1 and forming the second pad PAD2 on the exposed portion of the top surface P1t of the first pad PAD1.

The formation of the mask pattern MP may include forming a mask layer to fully cover the first pad PAD1 and removing a portion of the mask layer through an exposure process, which is performed on the mask layer. The mask pattern MP may have a pad opening POP. The pad opening POP may be formed on the top surface P1t of the first pad PAD1 to expose a portion of the top surface P1t of the first pad PAD1. The pad opening POP may have a side surface that is inclined at an angle to the top surface P1t of the first pad PAD1. For example, the pad opening POP may have an increasing width as a distance from the top surface P1t of the first pad PAD1 increases, but the inventive concept is not limited to this example.

The formation of the second pad PAD2 may be performed by a plating process. In some example embodiments, the plating process may include a nickel (Ni) plating process and/or a gold (Au) plating process, and in this case, the second pad PAD2 may contain nickel (Ni) and/or gold (Au). The plating process may be performed until a thickness of the second pad PAD2 from the top surface P1t of the first pad PAD1 has the first thickness T1. For example, the second pad PAD2 may fill a lower portion of the pad opening POP of the mask pattern MP.

Since the side surface of the mask pattern MP is inclined to the top surface P1t of the first pad PAD1, the side surface P2s of the second pad PAD2 may also be inclined to the top surface P1t of the first pad PAD1. For example, the second pad PAD2 may have an increasing width as a distance from the top surface P1t of the first pad PAD1 increases. The second pad PAD2 may have a first width W1 at the top surface P2t thereof. The second pad PAD2 may have a second width W2, which is smaller than the first width W1, at the bottom surface P2b thereof. The side surface P2s of the second pad PAD2 may be inclined at a constant angle θ to a direction perpendicular to the top surface P1t of the first pad PAD1. For example, the angle θ may range from about 3° to about 20°.

Referring to FIGS. 9A, 9B, and 9C, the protection pattern 550 may be formed on the upper redistribution layer 500. The formation of the protection pattern 550 may include forming a protection layer to cover the redistribution pad 540 and removing a portion of the protection layer to expose the second pad PAD2. For example, the partial removal of the protection layer may be performed through an etching process, a drilling process, a laser ablation process, or a laser cutting process.

The protection pattern 550 may have a thickness that is larger than a thickness of the second pad PAD2. That is, the protection pattern 550 may have the second thickness T2 in a vertical direction, and here, the second thickness T2 may be larger than the first thickness T1 of the second pad PAD2. Accordingly, the top surface 550t of the protection pattern 550 may be located at a level higher than the top surface P2t of the second pad PAD2.

The protection pattern 550 may cover the side surface and the top surface P1t of the first pad PAD1 and may expose the top surface P2t of the second pad PAD2. The bottom surface of the protection pattern 550 may be in contact with the top surface P1t of the first pad PAD1, and the side surface 550s of the protection pattern 550 may be in contact with the side surface P2s of the second pad PAD2. Accordingly, the protection pattern 550 may have the side surface 550s that is inclined at an angle to the top surface P1t of the first pad PAD1.

The protection pattern 550 may include the resin 550b and the fillers 550a, which are placed in the resin 550b. The fillers 550a may be enclosed by the resin 550b. For example, the protection pattern 550 may include at least one of inorganic fillers (e.g., prepreg, Ajinomoto build-up film (ABF), FR-4, and/or bismaleimide triazine (BT)), and/or resins containing glass fibers.

Thereafter, a curing process may be performed on the protection pattern 550. The protection pattern 550 may be shrunken by the curing process. In addition, a bonding strength between the protection pattern 550 and the first pad PAD1 may be greater than a bonding strength between the protection pattern 550 and the second pad PAD2. Accordingly, the protection pattern 550 may be easily detached from the second pad PAD2. Since the side surface 550s of the protection pattern 550 is horizontally spaced apart from the side surface P2s of the second pad PAD2, a gap GAP may be formed between the protection pattern 550 and the second pad PAD2.

The shrinkage of the protection pattern 550 may rely on the process time and/or process temperature in the curing process. For example, as the process time and/or process temperature in the curing process increase, the shrinkage of the protection pattern 550 may increase. This may mean that by adjusting the process time and/or process temperature in the curing process, it is possible to variously control the shape and size of a gap region between the protection pattern 550 and the second pad PAD2. For example, the protection pattern 550 may be spaced apart from the second pad PAD2 by a constant distance. A distance between the side surface P2s of the second pad PAD2 and the side surface 550s of the protection pattern 550 may be a third width W3, when measured at the top surface P2t of the second pad PAD2. The distance between the side surface P2s of the second pad PAD2 and the side surface 550s of the protection pattern 550 may be a fourth width W4, when measured at the bottom surface P2b of the second pad PAD2. In some example embodiments, the third width W3 may be substantially equal to the fourth width W4, as shown in FIG. 2A.

In some example embodiments, the protection pattern 550 may be detached from the first pad PAD1. As shown in FIG. 2B, a portion of the bottom surface of the protection pattern 550 may be spaced apart from the top surface P1t of the first pad PAD1 in a vertical direction. A space may be formed between the protection pattern 550 and the first pad PAD1. For example, the process time and/or process temperature in the curing process of FIG. 2B may be greater than the process time and/or process temperature in the curing process of FIG. 2A.

In some example embodiments, a distance from the protection pattern 550 to the second pad PAD2 may not be constant. As shown in FIG. 2C, the third width W3 may be larger than the fourth width W4. That is, the gap GAP between the protection pattern 550 and the second pad PAD2 may become narrow as a distance to the top surface P1t of the first pad PAD1 decreases. For example, the process time and/or process temperature in the curing process of FIG. 2C may be smaller than the process time and/or process temperature in the curing process of FIG. 2A.

Referring to FIGS. 10A, 10B, and 2A, the interposer substrate 600, on which the second semiconductor chip 700 is mounted, may be mounted on the upper redistribution layer 500. The connection terminals 650 may be provided on the lower pads 630 of the interposer substrate 600, respectively. The mounting of the interposer substrate 600 may include placing each of the connection terminals 650 on a corresponding one of the redistribution pads 540 and bonding each of the connection terminals 650 to the second pad PAD2 of the redistribution pad 540.

The placing of the connection terminal 650 may include placing the connection terminal 650 between the side surfaces 550s of the protection pattern 550. The top surface 550t of the protection pattern 550 may be located at a level higher than the top surface P2t of the second pad PAD2. Accordingly, the connection terminal 650 may be easily placed between the side surfaces 550s of the protection pattern 550. That is, the protection pattern 550 may be used as a guide precisely placing the connection terminal 650. Since the connection terminal 650 is placed between the side surfaces 550s of the protection pattern 550, the connection terminal 650 may be in contact with the top surface P2t of the second pad PAD2.

The bonding of the connection terminal 650 and the second pad PAD2 may be performed through a reflow process. In this case, the connection terminal 650 may be melted by the reflow process, and the fluidity of the connection terminal 650 may be increased. In addition, a reactivity between the connection terminal 650 and the second pad PAD2 may be greater than a reactivity between the connection terminal 650 and the protection pattern 550. Accordingly, the melted portion of the connection terminal 650 may flow to a region on the side surface P2s of the second pad PAD2, rather than the top surface 550t of the protection pattern 550. Thus, the connection terminal 650 may be formed to fill the gap GAP between the second pad PAD2 and the protection pattern 550.

In other words, the connection terminal 650 may be formed to include the first portion P1, which is placed on the second pad PAD2, and the second portion P2, which is extended from the first portion P1 into the gap GAP. That is, the bonding of the connection terminal 650 and the second pad PAD2 may include forming the first portion P1 of the connection terminal 650 and forming the second portion P2 of the connection terminal 650. Since the second portion P2 of the connection terminal 650 has an anchoring structure between the protection pattern 550 and the second pad PAD2, it may be possible to prevent or reduce in likelihood the detaching issue of the connection terminal 650. Thus, the reliability of the semiconductor package may be improved.

According to some example embodiments of the inventive concepts, a semiconductor package may include a connection terminal which is in contact with top and side surfaces of a pad. In this case, a contact area between the connection terminal and the pad may be increased. Thus, the electrical characteristics of the semiconductor package may be improved.

In addition, the connection terminal may include a first portion, which is provided on the pad, and a second portion, which is extended in an inclined direction between a protection pattern and the pad. The second portion of the connection terminal may have an anchoring structure, between the protection pattern and the pad. Thus, it may be possible to prevent or reduce in likelihood the connection terminal from being detached from the pad. Furthermore, the second portion of the connection terminal may be configured to relieve a pressure exerted downward from the outside of the semiconductor package. Thus, the reliability of the semiconductor package may be improved.

While example embodiments of the inventive concepts have been particularly shown and described, it will be understood by one of ordinary skill in the art that variations in form and detail may be made therein without departing from the spirit and scope of the attached claims.

1. A semiconductor package, comprising:
a semiconductor chip;
a redistribution layer on the semiconductor chip;
a protection pattern covering the redistribution layer; and
a connection terminal on the redistribution layer,
wherein the redistribution layer includes a redistribution pad on a top surface of the redistribution layer,
the redistribution pad includes a first pad and a second pad on the first pad,
the second pad has a side surface that is inclined and that extends to a top surface of the first pad, and
the protection pattern is spaced apart from the side surface of the second pad and has a side surface that is inclined and that extends to the top surface of the first pad.

2. The semiconductor package of claim 1, wherein the connection terminal includes a first portion on the second pad and a second portion extending between the side surface of the second pad and the side surface of the protection pattern.

3. The semiconductor package of claim 2, wherein the second portion is in contact with the top surface of the first pad.

4. The semiconductor package of claim 2, wherein the second portion has a width that decreases as a distance to the first pad decreases.

5. The semiconductor package of claim 2, wherein the connection terminal further includes a third portion extending from the second portion to a region between a bottom surface of the protection pattern and the top surface of the first pad.

6. The semiconductor package of claim 1, wherein a width of the second pad increases as a distance from the top surface of the first pad increases.

7. The semiconductor package of claim 1, wherein a width of the second pad decreases as a distance from the top surface of the first pad increases.

8. The semiconductor package of claim 1, wherein a top surface of the protection pattern is higher than a top surface of the second pad.

9. The semiconductor package of claim 1, wherein the protection pattern covers a side surface of the first pad and a portion of the top surface of the first pad, and the protection pattern exposes the second pad.

10. The semiconductor package of claim 1, wherein the second pad vertically overlaps the first pad.

11. The semiconductor package of claim 1, wherein a width of the first pad is larger than a width of the second pad.

12. The semiconductor package of claim 1, wherein a roughness of the side surface of the protection pattern is greater than a roughness of the side surface of the second pad.

13. The semiconductor package of claim 1, wherein the first pad and the second pad include different metallic materials from each other.

14. The semiconductor package of claim 1, wherein the side surface of the second pad is inclined at an angle of 3° to 20° to a direction perpendicular to the top surface of the first pad.

15. A semiconductor package, comprising:
a lower redistribution layer;
a first semiconductor chip on the lower redistribution layer;
an upper redistribution layer on the first semiconductor chip, the upper redistribution layer including a redistribution pad on a top surface of the upper redistribution layer;
a second semiconductor chip on the upper redistribution layer;
a connection terminal electrically connecting the second semiconductor chip to the upper redistribution layer; and
a protection pattern on the upper redistribution layer,
wherein the redistribution pad includes a first pad and a second pad on the first pad,
the protection pattern has a side surface on the first pad and the side surface of the protection pattern is spaced apart from a side surface of the second pad, and
the connection terminal includes a first portion on a top surface of the second pad and a second portion between the side surface of the second pad and the side surface of the protection pattern.

16. The semiconductor package of claim 15, wherein a width of the first pad is larger than a width of the second pad, and
the first pad and the second pad vertically overlap each other.

17. The semiconductor package of claim 15, wherein the second portion extends in an inclined direction to a top surface of the first pad, and the second portion is in contact with the top surface of the first pad.

18. The semiconductor package of claim 15, wherein a vertical length of the second portion ranges from 3 μm to 5 μm, and
a horizontal width of the second portion ranges from 1 μm to 4 μm.

19. The semiconductor package of claim 15, wherein the first pad includes copper (Cu), and
the second pad includes nickel (Ni) or gold (Au).

20. A semiconductor package, comprising:
a lower redistribution layer;
a logic chip on the lower redistribution layer;
a connection substrate on the lower redistribution layer enclosing the logic chip in a plan view;
a mold layer covering the logic chip and the connection substrate;
an upper redistribution layer on the mold layer, the upper redistribution layer including redistribution pads;
a protection pattern covering the upper redistribution layer;
a memory chip on the upper redistribution layer; and
connection terminals on corresponding ones of the redistribution pads, the connection terminals between the upper redistribution layer and the memory chip,
wherein each of the redistribution pads includes a first pad and a second pad on the first pad,
the protection pattern covers the first pad and is horizontally spaced apart from the second pad,
each of the connection terminals include a first portion on the second pad and a second portion extending between the second pad and the protection pattern, and
the second pad and the protection pattern have side surfaces that are inclined and that extend to a top surface of the first pad.

21-25. (canceled)
